(19) United States
(12) Patent Application Publication
(10) Pub. No.: US 2026/0343951 A1
(43) Pub. Date: Oct. 29, 2026

(54) SPUTTERING TARGET FOR FORMATION OF OXIDE SEMICONDUCTOR THIN FILM, METHOD FOR PRODUCING SPUTTERING TARGET FOR FORMATION OF OXIDE SEMICONDUCTOR THIN FILM, OXIDE SEMICONDUCTOR THIN FILM, THIN FILM SEMICONDUCTOR DEVICE AND METHOD FOR PRODUCING SAME

(71) Applicant: Ulvac, Inc., Chigasaki-shi, Kanagawa (JP)

(72) Inventors: Kenta TANINO, Chigasaki-shi (JP); Taku HANNA, Chigasaki-shi (JP); Masato TAKEUCHI, Chigasaki-shi (JP); Naoto TEZUKA, Chigasaki-shi (JP)

(21) Appl. No.: 19/110,940

(22) PCT Filed: Jun. 29, 2023
(86) PCT No.: PCT/JP2023/024260

§ 371 Date: Mar. 12, 2025

(30) Foreign Application Priority Data
Sep. 16, 2022 (JP) 2022-148521

(51) Int. Cl. H10D 30/67; C23C 14/34; H10D 30/01; H10P 14/20; H10P 14/22

(52) U.S. Cl. CPC H10D 30/6755; C23C 14/3414; H10D 30/0316; H10P 14/22; H10P 14/3434; H10D 30/6732

(57) ABSTRACT

To realize a sputtering target for forming an oxide semiconductor thin film, which target can provide an oxide semiconductor thin film suited for an active layer achieving both high electron mobility and wide band gap; a production method therefor; an oxide semiconductor thin film; a thin film semiconductor device, and a method for producing the semiconductor device. In the sputtering target for forming an oxide semiconductor thin film which target can form an oxide semiconductor thin film, the target is formed of an oxide sintered body containing a specific oxide, and the specific oxide has elemental proportions represented by In_{X}Sn_{Y}Ga_{Y}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied.

Sputtering Target for Formation of Oxide Semiconductor Thin Film, Method for Producing Sputtering Target for Formation of Oxide Semiconductor Thin Film, Oxide Semiconductor Thin Film, Thin Film Semiconductor Device and Method for Producing Same

### TECHNICAL FIELD

The present invention relates to a sputtering target for forming an oxide semiconductor thin film, to a method for producing the sputtering target for forming an oxide semiconductor thin film, to an oxide semiconductor thin film, to a thin film semiconductor device, and to a method for producing the semiconductor device.

### BACKGROUND ART

In recent years, a thin film transistor (TFT) employing an In—Ga—Zn—O-type oxide (IGZO) semiconductor thin film serving as an active layer has been widely adapted to a variety of display devices, since higher electron mobility can be achieved as compared with a conventional TFT employing an amorphous silicon film as an active layer (see, for example, Patent Documents 1 to 3).

Specifically, Patent Document 1 discloses an organic EL display device which employs a TFT having an active layer for driving an organic EL element, the layer being formed of IGZO. Patent Document 2 discloses a thin film transistor which has a channel layer (active layer) formed of a-IGZO and which exhibits an electron mobility of 5 cm²/Vs or higher. Patent Document 3 discloses a thin film transistor which has an active layer formed of IGZO and which exhibits an on/off current ratio of 104 or greater.

Meanwhile, from the viewpoint of reducing the material cost of IGZO, there have also been proposed Zn—Sn—O (ZTO) (Patent Document 4) and In—Sn—Zn—O (ITZO), containing Sn instead of Ga present in IGZO (Patent Document 5). In particular, ITZO, having an electron mobility considerably higher than that of IGZO, will be a promising material next to IGZO.

However, among many materials of an oxide semiconductor, ITZO has a large thermal expansion coefficient and low thermal conductivity. Thus, ITZO is not suited from a sputtering target. In order to solve the problem, there has been proposed a sputtering target formed of an oxide sintered body which contains elements In+Sn+Zn+X and oxygen, which has atomic proportions of the elements satisfying the following formula (1), and which includes a spinel-type compound represented by Zn₂SnO₄ (Patent Document 6).

0.001≤X/(In+Sn+Zn+X)≤0.05 (1)

(In formula (1), element X is at least one element selected from Ge, Si, Y, Zr, Al, Mg, Yb, and Ga.)

### PRIOR ART DOCUMENTS

### Patent Documents

Patent Document 1: Japanese Patent Application Laid-Open (kokai) No. 2009-31750
Patent Document 2: Japanese Patent Application Laid-Open (kokai) No. 2011-216574
Patent Document 3: WO 2010/092810
Patent Document 4: Japanese Patent Application Laid-Open (kokai) No. 2017-36497
Patent Document 5: WO 2013/179676
Patent Document 6: WO 2019/026954

### SUMMARY OF THE INVENTION

### Problems to be Solved by the Invention

In recent years, there is increasing demand for oxide semiconductors exhibiting higher electron mobility, in order to satisfy requirements for higher resolution, low power consumption, and higher frame rate of various display devices. However, in thin film transistors employing an active layer formed of IGZO, difficulty is encountered in achieving an electron mobility higher than 10 cm²/Vs. Thus, there is demand for a material used in a thin film transistor exhibiting higher electron mobility.

As another problem, when IGZO is used in a high-electron mobility active layer, a rise in threshold voltage at a current on/off timing is shifted. That is, a high-electron mobility active layer tends to have a small band gap, which is problematic.

Thus, it is important for an active layer of a TFT employed in a high-function display to have high electron mobility and wide band gap in a well-balanced manner. When this condition is satisfied, light resistance of the display is enhanced, to thereby achieve high reliability. However, there has never been elucidated an optimum compositional proportions of such an active layer from the aforementioned viewpoint.

In addition, when a thin film transistor material is used as an active layer of a TFT, the etching rate of the material with respect to a specific etchant is also a key point.

Under such circumstances, an object of the present invention is to provide a sputtering target for forming an oxide semiconductor thin film which target can provide an oxide semiconductor thin film suited for an active layer achieving both high electron mobility and wide band gap, and a production method therefor. Other objects are to provide an oxide semiconductor thin film, a thin film semiconductor device, and a method for producing the semiconductor device.

### Means for Solving the Problems

The inventors have conducted extensive studies in order to attain the aforementioned objects, and have found that a thin film of an oxide containing indium, zinc, and tin, and also gallium and germanium is suited for an active layer to be realized. The present invention has been accomplished on the basis of this finding.

Accordingly, the present invention includes the following.

In a first mode of the present invention, there is provided a sputtering target for forming an oxide semiconductor thin film which target can form an oxide semiconductor thin film, wherein
the target is formed of an oxide sintered body containing a specific oxide, and
the specific oxide has elemental proportions represented by In_{X}Sn_{Y}GaᵥGe_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied.

A second mode of the present invention is directed to a specific embodiment of the sputtering target for forming an oxide semiconductor thin film of the first mode, wherein
the oxide sintered body further contains a group A element, which is defined as at least one element selected from among Ti, Ta, Zr, Y, Al, Mg, and Sb.

A third mode of the present invention is directed to a specific embodiment of the sputtering target for forming an oxide semiconductor thin film of the second mode, wherein
the target contains Ti in an amount of 2 at % or less, Ta in an amount of 2 at % or less, Zr in an amount of 3 at % or less, Y in an amount of 4 at % or less, Al in an amount of 5 at& or less, Mg in an amount of 5 at % or less, and Sb in an amount of 9 at % or less, and
the group A element content is less than 10 at %.

A fourth mode of the present invention is directed to a specific embodiment of the sputtering target for forming an oxide semiconductor thin film of any one of the first to third modes, wherein
the target has a relative density of 90% or more.

In a fifth mode of the present invention, there is provided a method for producing a sputtering target for forming an oxide semiconductor thin film which target can form an oxide semiconductor thin film, the method comprising
mixing indium oxide powder, tin oxide powder, zinc oxide powder, gallium oxide powder, and germanium oxide powder, to thereby form a compact, and firing the compact at 1, 100 °C to 1,650 °C, to thereby yield a sputtering target for forming an oxide semiconductor thin film, the target having an oxide sintered body as recited in any one of the first to fourth modes.

In a sixth mode of the present invention, there is provided a method for producing a sputtering target for forming an oxide semiconductor thin film which target can form an oxide semiconductor thin film, the method comprising
mixing an oxide, a hydroxide, or a carbonate salt of indium, tin, zinc, gallium, and germanium; calcining the mixture at 600 °C to 1,500 °C, to thereby form a precursor powder; molding the precursor powder, to thereby form a compact; and firing the compact at 1,100 °C to 1,650 °C, to thereby yield a sputtering target for forming an oxide semiconductor thin film, the target having an oxide sintered body as recited in any one of the first to fourth modes.

In a seventh mode of the present invention, there is provided an oxide semiconductor thin film, wherein
the thin film is formed of an oxide semiconductor containing a specific oxide, and
the specific oxide has elemental proportions represented by In_{X}Sn_{Y}Ga_{V}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied.

An eighth mode of the present invention is directed to a specific embodiment of the oxide semiconductor thin film of the seventh mode, which exhibits an electron mobility of 15 to 30 cm²/V·s and a band gap of 2.75 eV or more.

A ninth mode of the present invention is directed to a specific embodiment of the oxide semiconductor thin film of the seventh or eighth mode, wherein
the etching rate in etching with a phosphoric acid-acetic acid-based etchant is 1 nm/sec or more.

A tenth mode of the present invention is directed to a specific embodiment of the oxide semiconductor thin film of any one of the seventh to ninth modes, wherein
the thin film further contains a group A element, which is defined as at least one element selected from among Ti, Ta, Zr, Y, Al, Mg, and Sb.

An eleventh mode of the present invention is directed to a specific embodiment of the oxide semiconductor thin film of the tenth mode, wherein
the thin film contains Ti in an amount of 2 at % or less, Ta in an amount of 2 at % or less, Zr in an amount of 3 at % or less, Y in an amount of 4 at % or less, Al in an amount of 5 at % or less, Mg in an amount of 5 at % or less, and Sb in an amount of 9 at % or less, and
the group A element content is less than 10 at %.

In a twelfth mode of the present invention, there is provided a thin film semiconductor device, which comprises
a gate electrode;
a gate insulating film disposed on the gate electrode;
an active layer formed of an oxide semiconductor thin film exhibiting a high electron mobility and disposed on the gate insulating film; and
a source electrode and a drain electrode which are connected to the active layer, wherein
the active layer is formed of an oxide semiconductor thin film as recited in any of the seventh to eleventh modes.

A thirteenth mode of the present invention is directed to a specific embodiment of the thin film semiconductor device of the twelfth mode, wherein
the device includes a cap layer which is disposed so as to cover the active layer.

A fourteenth mode of the present invention is directed to a specific embodiment of the thin film semiconductor device of the thirteenth mode, wherein
the cap layer has an etching rate suited for patterning with the active layer.

In a fifteenth mode of the present invention, there is provided a method for producing a thin film semiconductor device as recited in the twelfth mode, the method comprising
forming a gate insulating film on a gate electrode;
forming an active layer formed of an oxide semiconductor thin film exhibiting a high electron mobility on the gate insulating film through sputtering;
patterning the active layer;
forming a metal layer disposed on the active layer which has been patterned and serves as an underlayer film; and
patterning the metal layer through wet etching, to thereby form a source electrode and a drain electrode.

In a sixteenth mode of the present invention, there is provided a method for producing a thin film semiconductor device as recited in the thirteenth or fourteenth mode, the method comprising
forming a gate insulating film on a gate electrode;
forming an active layer formed of an oxide semiconductor thin film exhibiting a high electron mobility on the gate insulating film through sputtering;
forming a cap layer on the active layer through sputtering;
patterning a stacked film of the active layer and the cap layer;
forming a metal layer disposed on the active layer and the cap layer which have been patterned and serve as an underlayer film; and
patterning the metal layer through wet etching, to thereby form a source electrode and a drain electrode.

### Effects of the Invention

According to the present invention, there can be provided a sputtering target for forming oxide semiconductor thin film, which target can form an oxide semiconductor thin film exhibiting a well balance in high electron mobility and wide band gap (most suitable for serving as an active layer of a TFT employed in a high-function display) and an etching rate suited for a specific etchant. As a result, light resistance of the display is enhanced, to thereby achieve high reliability.

### BRIEF DESCRIPTION OF THE DRAWINGS

FIG. 1 A chart showing a measured electron mobility (15 to 30 cm²/V·s) profile of a thin film of ternary complex oxide of In, Sn, and Zn.

FIG. 2 A chart showing a band gap (2.75 eV or more) profile of a thin film of ternary complex oxide of In, Sn, and Zn.

FIG. 3 A chart showing an etching rate (1 nm/sec or more) profile of a thin film of a ternary complex oxide of In, Sn, and Zn, with respect to a phosphoric acid-acetic acid-based etchant.

FIG. 4 A chart showing an integrated range of FIGS. 1 to 3.

FIG. 5 A schematic view of a schematic configuration of an example of the thin film transistor of the present invention.

FIG. 6 A schematic view of a schematic configuration of another example of the thin film transistor of the present invention.

FIG. 7 A series of exemplary schematic views of a method of producing the thin film transistor of the present invention.

FIG. 8 A series of exemplary schematic views of a method of producing the thin film transistor of the present invention.

FIG. 9 Graphs showing comparison in initial characteristics of thin film transistors falling within the scope of the present invention (Examples 21 and 22) and a thin film transistor of Comparative Example 21, graphs (a), (b), and (c) corresponding to Example 21, Example 22, and Comparative Example 21, respectively.

FIG. 10 Graphs showing comparison in PBTS of thin film transistors falling within the scope of the present invention (Examples 21 and 22) and a thin film transistor of Comparative Example 21, graphs (a), (b), and (c) corresponding to Example 21, Example 22, and Comparative Example 21, respectively.

FIG. 11 Graphs showing comparison in NBTS of thin film transistors falling within the scope of the present invention (Examples 21 and 22) and a thin film transistor of Comparative Example 21, graphs (a), (b), and (c) corresponding to Example 21, Example 22, and Comparative Example 21, respectively.

FIG. 12 Graphs showing comparison in NBITS of thin film transistors falling within the scope of the present invention (Examples 21 and 22) and a thin film transistor of Comparative Example 21, graphs (a), (b), and (c) corresponding to Example 21, Example 22, and Comparative Example 21, respectively.

FIG. 13 Graphs showing comparison in initial characteristics of thin film transistors falling within the scope of the present invention (Examples 23 and 24) and a thin film transistor of Comparative Example 22, graphs (a), (b), and (c) corresponding to Example 23, Example 24, and Comparative Example 22, respectively.

FIG. 14 Graphs showing comparison in PBTS of thin film transistors falling within the scope of the present invention (Examples 23 and 24) and a thin film transistor of Comparative Example 22, graphs (a), (b), and (c) corresponding to Example 23, Example 24, and Comparative Example 22, respectively.

FIG. 15 Graphs showing comparison in NBTS of thin film transistors falling within the scope of the present invention (Examples 23 and 24) and a thin film transistor of Comparative Example 22, graphs (a), (b), and (c) corresponding to Example 23, Example 24, and Comparative Example 22, respectively.

FIG. 16 Graphs showing comparison in NBITS of thin film transistors falling within the scope of the present invention (Examples 23 and 24) and a thin film transistor of Comparative Example 22, graphs (a), (b), and (c) corresponding to Example 23, Example 24, and Comparative Example 22, respectively.

### MODES FOR CARRYING OUT THE INVENTION

In reference to the drawings, embodiments of the present invention will be described.

Before mentioning the sputtering target for forming an oxide semiconductor thin film according to the present embodiment, characteristics of the oxide semiconductor thin film formed from the sputtering target will be described in detail.

### [Oxide Semiconductor Thin Film]

An oxide semiconductor thin film is employed as, for example, a high-electron mobility active layer (i.e., an inversion layer) of a so-called bottom gate-type thin film transistor (e.g., a field effect transistor).

The term “high-electron mobility active layer” refers to an active layer exhibiting an electron mobility is 15 to 30 cm²/V·s and a band gap of 2.75 eV or more.

The oxide semiconductor thin film of the present invention is formed of an oxide semiconductor sintered body containing a specific oxide, and the specific oxide has elemental proportions represented by In_{X}Sn_{Y}Ga_{V}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied.

In the present invention, the composition of elements is provided in the following manner. That is, In is used as a carrier-generator; Sn is used for its functions of controlling etching and electron mobility; Zn is used for its etching control function; and Ge is additionally used to serve as a carrier-killer. The ternary element system In—Sn—Zn realizes high electron mobility and wide band gap. A specific amount of Ge is added, so as to define conditions under which a high etching rate with respect to a specific etchant is attained. Even when the amount of Ge increases, Ge does not cause a considerable drop in band gap and does less affect the etching rate. Furthermore, a specific amount of Ga is added, since Ga has functions of controlling electron mobility and etching with respect to a phosphoric acid-acetic acid-based etchant.

The aforementioned 5-component system composition has been established on the basis of the finding of the inventors. Specifically, when various elements were added to the In—Zn mixture system (1:1), the relationship between the amount of each of the added elements and a drop in electron mobility, and the relationship between the amount of each of the added elements and an increase in band gap were determined.

More specifically, the inventors have found that a system of In and Zn to which Ge has been added exhibits a small drop in electron mobility and a large increase in band gap, by adding various elements to the In—Zn mixture system (1:1) and investigating the relationship between the amount of each of the added elements and a drop in electron mobility.

Also, the inventors have also found that addition of Sn is effective for controlling etching and electron mobility, by adding various elements to the In—Zn mixture system (1:1) and investigating the relationship between the amount of each of the added elements and an increase in band gap.

In the case where a phosphoric acid-acetic acid-based etchant is used, the inventors have also found that, elements Ge and Ga result in a small drop in etching rate when added, with Ga resulting in a particularly small drop.

Therefore, in the present invention, the compositional ranges in the 5-component-system composition (In—Zn—Sn—Ga—Ge) in which high electron mobility, wide band gap, and high etching rate with respect to a specific etchant are attained are determined through the following procedure.

Firstly, in the ternary-system In_{X}Sn_{Y}Zn_{Z} oxide semiconductor, the relationships between the compositional proportions and the electron mobility, the band gap, and the etching rate with respect to a specific etchant are determined. The etchant is a phosphoric acid-acetic acid-based etchant, more specifically, a PAN, which is a liquid mixture containing phosphoric acid (H₃PO₄, <80%), nitric acid (HNO₃, <5%), and acetic acid (CH₃COOH, <10%).

In each of In, Sn, and Zn, the compositional range under which an electron mobility of 15 to 30 cm²/V·s, a band gap of 2.75 eV or more, and an etching rate of 1 nm/sec or more are attained is determined. On the basis of the results, an overlapping range of the three ranges is determined.

Firstly, the electron mobility of a ternary (In—Sn—Zn) complex oxide thin film is measured, to thereby define a compositional range under which the electron mobility falls within a range of 15 to 30 cm²/V·s. The electron mobility is measured in the following manner.

A square sample (10 mm×10 mm) of a semiconductor is provided, and a metal is applied onto an area of each corner, to thereby form contact portions.

Then, a current is applied to the sample, and a magnetic field vertical to the current is applied, to thereby generate electromotive force vertical to both the applied current and the magnetic field, which is determined as Hall electromotive force.

The Hall electromotive force is proportional to the applied current and the magnetic field, and the coefficients of proportion are physical quantities intrinsic a sample.

In addition to the coefficients and electrical conductivity (i.e., electrical resistance) of a sample is measured, to thereby obtain information of the sample (e.g., electron mobility).

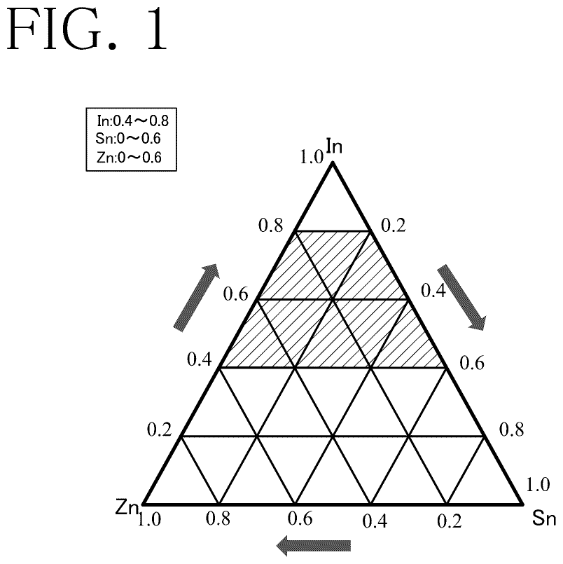

FIG. 1 shows the results. As is clear from FIG. 1, the compositional ranges under which the electron mobility is 15 to 30 cm²/V·s are 0.4≤X<0.8, 0≤Y≤0.6, and 0≤Z≤0.6. The compositional ranges are preferred, since a target high electron mobility can be achieved.

Next, the band gap of an In—Sn—Zn ternary composite oxide thin film is determined through the following procedure.
1. Transmittance T and reflectance R are measured by means of a spectrometer.
2. Absorption coefficient α is calculated by the following equation:

α=(((-ln(T/(1-R))/n)/(T/(1-R))

(wherein n represents a thickness [cm], and each of T and R is measurement/100).
3. (α×hω)\hat{ }(½) is calculated.
   (In the equation, hω represents energy of a photon [eV]: 1239.8/wavelength [nm].)
4. In a graph showing the relationship between hω [eV] (horizontal axis) and (α×hω)\hat{ }(½) (vertical axis), the value of an intersection point between a tangential line having a maximum slope and the x-axis is employed as a band gap.

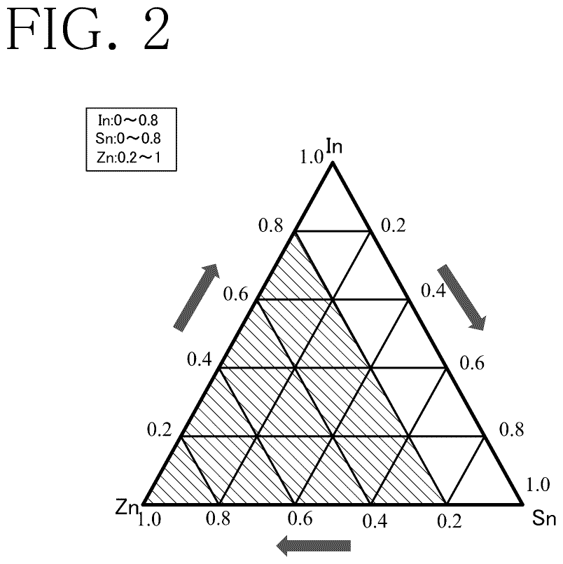

FIG. 2 shows the results. As is clear from FIG. 2, the compositional ranges under which the band gap is 2.75 eV or more are 0≤X≤0.8, 0≤Y≤0.8, and 0.2≤Z≤1. The band gap is preferably 2.75 eV or more, since high electron mobility and wide band gap can be realized in the band gap range.

Next, the compositional ranges under which the etching rate with respect to a phosphoric acid-acetic acid-based etchant is 1 nm/sec or more are determined. The employed etchant is PAN, which is a liquid mixture containing phosphoric acid (H₃PO₄, <80%), nitric acid (HNO₃, <5%), and acetic acid (CH₃COOH, <10%). The etching rate is determined through Dip method, in which a single-film cap layer formed of an as-formed oxide semiconductor thin film is immersed in an etchant controlled at 40 °C.

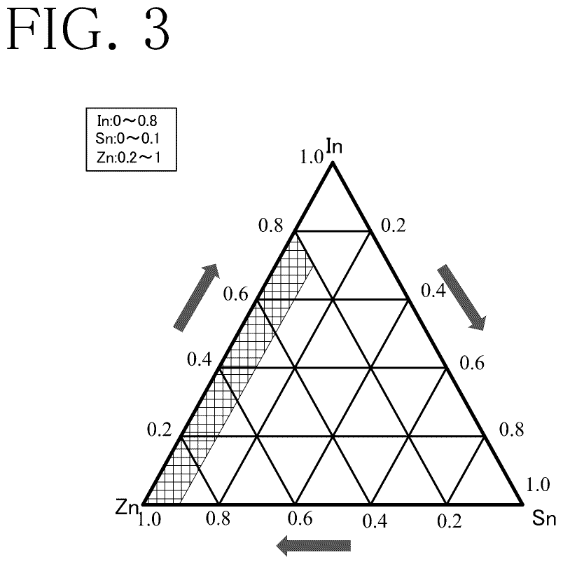

FIG. 3 shows the results. As is clear from FIG. 3, the compositional ranges under which the etching rate is 1 nm/sec or more are 0≤X≤0.8, 0≤Y≤0.1, and 0.2≤Z≤1.

The compositional ranges are required for realizing high electron mobility and wide band gap, and high etching rate with respect to a phosphoric acid-acetic acid-based etchant.

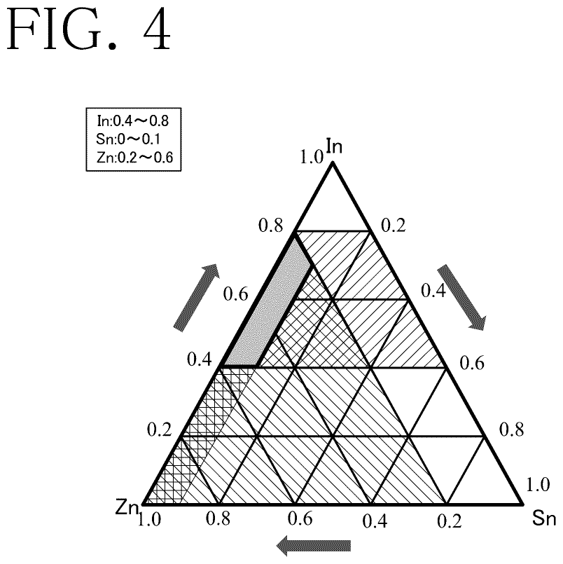

FIG. 4 shows the integrated feature of the results in terms of the compositional ranges of FIGS. 1 to 3. As is clear from FIG. 4, all of the aforementioned elements are achieved, when, in In_{X}Sn_{Y}Ge_{w}Zn_{Z}, X is 0.4 to 0.8, Y is 0 to 0.1, and Z is 0.2 to 0.6, and conditions X+Y+Z=1 are satisfied. The compositional ranges are provided, since high electron mobility and wide band gap, and high etching rate with respect to a sulfuric acid-nitric acid-based etchant, which are targets of the present invention, can be realized, even when Ge is added.

In addition, when W/(V+W+X+Y+Z) (i.e., an index for the amount of Ge added) is 0.01 to 0.03, a high electron mobility of 15 to 30 cm²/V·s, a wide band gap of 2.75 eV or more, and an etching rate in etching with a phosphoric acid-acetic acid-based etchant of 1 nm/sec or more are found to be achieved.

The oxide semiconductor thin film of the present invention may further contain a group A element, which is defined as at least one element selected from among Ti, Ta, Zr, Y, Al, Mg, and Sb.

Preferably, the amount of group A elements added are as follows: Ti in an amount of 2 at % or less, Ta in an amount of 2 at& or less, Zr in an amount of 3 at % or less, Y in an amount of 4 at % or less, Al in an amount of 5 at % or less, Mg in an amount of 5 at % or less, and Sb in an amount of 9 at % or less, and the group A element content is less than 10 at %, so that the oxide semiconductor thin film can exhibit a high electron mobility of 10 cm²/V·s or higher and a wide band gap of 2.75 eV or more.

TABLE 1

| | Amount of added (at %) | | | | | | | | | | | | | | | | | | | |
|---|---|---|---|---|---|---|---|---|---|---|---|---|---|---|---|---|---|---|---|---|
| α | 1 | 2 | 3 | 4 | 5 | 6 | 7 | 8 | 9 | 10 | 11 | 12 | 13 | 14 | 15 | 16 | 17 | 18 | 19 | 20 |
| Ti | ◯ | ◯ | X | X | X | X | X | X | X | X | X | X | X | X | X | X | X | X | X | X |
| Ta | ◯ | ◯ | X | X | X | X | X | X | X | X | X | X | X | X | X | X | X | X | X | X |
| Zr | ◯ | ◯ | ◯ | X | X | X | X | X | X | X | X | X | X | X | X | X | X | X | X | X |
| Y | ◯ | ◯ | ◯ | ◯ | X | X | X | X | X | X | X | X | X | X | X | X | X | X | X | X |
| Al | ◯ | ◯ | ◯ | ◯ | ◯ | X | X | X | X | X | X | X | X | X | X | X | X | X | X | X |
| Mg | ◯ | ◯ | ◯ | ◯ | ◯ | X | X | X | X | X | X | X | X | X | X | X | X | X | X | X |
| Sb | ◯ | ◯ | ◯ | ◯ | ◯ | ◯ | ◯ | ◯ | ◯ | X | X | X | X | X | X | X | X | X | X | X |

### [Sputtering Target]

Next will be described an embodiment of the sputtering target of the invention.

The sputtering target may be a planar-shape target or a cylindrical rotary target. The sputtering target is formed of a sintered body of an oxide containing In, Sn, Ga, Ge, and Zn, and the compositional proportions and preferred compositional proportions thereof are the same as those of the aforementioned oxide semiconductor thin film. Thus, overlapping descriptions will be omitted.

In the oxide sintered body of the sputtering target of the present invention, the elemental proportion of the sintered body of the oxide is represented by In_{X}Sn_{Y}Ga_{Y}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied.

The oxide sintered body forming the sputtering target of the present invention may further contain a group A element, which is defined as at least one element selected from among Ti, Ta, Zr, Y, Al, Mg, and Sb.

Regarding the above group A elements, preferably, the oxide contains Ti in an amount of 2 at % or less, Ta in an amount of 2 at % or less, Zr in an amount of 3 at % or less, Y in an amount of 4 at % or less, Al in an amount of 5 at % or less, Mg in an amount of 5 at % or less, and Sb in an amount of 9 at % or less, and the total group A element content is less than 10 at %.

Also, the elemental proportions of the oxide semiconductor thin film sputtered from the oxide sintered body are preferably such that a high electron mobility of 15 to 30 cm²/V·s and a wide band gap of 2.75 eV or more are successfully achieved.

The oxide semiconductor thin film formed from such a sputtering target of the present invention can achieve a high electron mobility of 15 to 30 cm²/V·s and a wide band gap of 2.75 eV or more. In addition, an etching rate of 1 nm/sec or more can be achieved with respect to a phosphoric acid-acetic acid-based etchant.

### (Sputtering Target Production Method)

No particular limitation is imposed on the sputtering target production method of the present invention, so long as a sintered body of the oxide having the aforementioned composition can be produced. Examples of the production method include the following two procedures.

In a first production method, an indium oxide powder, a tin oxide powder, a zinc oxide powder, a gallium oxide powder, and a germanium oxide powder are mixed together, and the mixture is molded into a compact. The compact is fired at 1,100 °C to 1,650 °C, to thereby yield a sputtering target having an oxide sintered body.

The proportions by weight of the raw material powders are predetermined so as to achieve the target element proportions of the aforementioned oxide sintered body.

In a second production method, an oxide, a hydroxide, or a carbonate salt of indium, tin, zinc, gallium, and germanium are mixed together, and the mixture is calcined at 600 °C to 1,500 °C, to thereby form a powder of a precursor. The precursor powder is molded into a compact, and the compact is fired at 1,100 °C to 1,650 °C, to thereby yield a sputtering target having an oxide sintered body.

The proportions by weight of the raw material powders are predetermined so as to achieve the target element proportions of the aforementioned oxide sintered body.

Hereinafter, the production method of the invention will be further described in detail, in reference to an embodiment of the second production method.

In the embodiment, raw material powders are granulated through spray drying, which allows drying and granulation to be conducted simultaneously. Spray drying is advantageous for easily achieving a uniform compositional distribution of the sputtering target, since, for example, a difficult crushing operation due to a poor crushability caused by addition of a binder can be omitted, and a powder material formed of spherical particles having high flowability can be used.

The raw material powders include at least an oxide, a hydroxide, or a carbonate salt of indium, tin, zinc, gallium, and germanium. In addition, the raw material powders may further include a powder of at least one species selected from the oxides of the group A element. In mixing of the raw material powders, a dispersant or the like may be added.

The raw material powders may be pulverized/mixed by means of a ball mill. Other than a ball mill, another medium agitation mill such as a bead mill or a rod mill may be employed. Balls and beads serving as an agitation medium may be surface-coated with a resin coating material or the like. As a result, contamination of the powder can be effectively prevented.

The thus-mixed particle powder is calcined at 600 °C to 1,500 °C. When the firing temperature is lower than 600 °C, calcination is insufficient, thereby failing to completely form a composite oxide. When the firing temperature is higher than 1,500 °C, sintering proceeds during calcination, and large primary particles are produced. In this case, the sintering density cannot further increase in subsequent firing for sintering.

The calcined powder is wet-pulverized again by means of a ball mill or the like, with a dispersant, a binder, or the like. The obtained powder is granulated through spray drying.

The mean particle size of the granulated powder is adjusted to be 500 μm or less. When the mean particle size of the granulated powder is in excess of 500 μm, cracking and breakage of the compact frequently occur, and particle-like spots emerge on the fired body. If such a fired body is employed as a sputtering target, anomalous discharge and particle generation may occur.

The granulated powder more preferably has a mean particle size of 20 μm to 100 μm. When the particle size falls within the range, the change in volume (i.e., compressibility) before and after cold isostatic press (CIP) molding is small, and generation of cracks of the compact is suppressed, whereby long-size compacts can be consistently produced. When the mean particle size is smaller than 20 μm, the powder tends to be blown up, leading to difficulty in handling.

As used herein, the term “mean particle size” refers to a 50% cumulative value of the particle size distribution determined by means of a sieve-type particle size distribution meter. A specific value of the mean particle size measured by means of “Robot Sifter RPS-105M” (product of Seishin Enterprise Co., Ltd.) is employed.

The granulated powder is molded at a pressure of 100 MPa/cm² or higher. Through this molding, a sintered body having a relative density of 97% or higher can be yielded. When the molding pressure is lower than 100 MPa, the formed compact tends to be broken; difficulty is encountered in handling; and the relative density of the sintered body decreases.

CIP is employed as the molding method. The mode of performing CIP may be a typical vertical load type (orthogonal mode), preferably a horizontal load type (lateral mode). If a long planar compact is produced in orthogonal-mode CIP, an unfixed portion of powder in the mold results in variation in thickness, and cracking occurs by self-weight in handling.

The compact is fired at 1, 100 °C to 1,650 °C, to thereby yield a sintered body.

When the firing temperature is lower than 1,100 °C, the conductivity and relative density of the product are low, which makes the product to be unfitted as a target. When the firing temperature is higher than 1,650 °C, a part of the components evaporates. In this case, the composition of the fired body may vary, and coarse crystal grains may be provided to reduce the mechanical strength of the fired body.

The compact is fired in air or an oxidizing atmosphere, whereby an oxide sintered body of interest can be consistently produced.

The granulated powder is produced from a powder formed of primary particles having a mean particle size of 0.3 μm to 1.5 μm. By use of the raw material powder, the time of mixing/pulverization can be shortened, and dispersibility of the raw material powder in the granulated powder can be enhanced.

The angle of repose of the granulated powder is preferably 32° or less. In this case, flowability of the granulated powder increases, whereby moldability and sinterability are enhanced.

### (Process Step)

The thus-fabricated sintered body is mechanically processed into a plate-form body having a shape, dimensions, and thickness of interest, to thereby yield a sputtering target formed of an In—Sn—Ga—Ge—Zn—O sintered body. The thus-obtained sputtering target is brazed onto a backing plate.

In this embodiment, a long-size sputtering target having a length greater than 1,000 mm to a longitudinal direction can be fabricated. Thus, a large-scale monolithic sputtering target can be provided. Since possible sputtering of a bonding material (a braze), which would otherwise be present in a joint (i.e., gap between target parts), is prevented, deterioration of the formed film can be prevented, whereby consistent film formation can be achieved. In addition, generation of particles, which would otherwise be caused by re-deposition of sputtered particles deposited in the aforementioned gap, can be suppressed.

### [Assessment of Sputtering Target]

### (Specific Resistivity Distribution)

Specific resistivity is determined through a DC 4-probe method by means of Model sigma-5+ (product of NPS).

After processing of a sintered body, specific resistivity is measured at 5 points of the surface on the sputtering side. The measurements are averaged, to thereby provide a specific resistivity value.

### (Relative Density)

The density of a sintered body is determined through the Archimedes' method by use of mercury, or through direct calculation of dimensions and weight.

### (Crystal Structure)

Formation of a composite oxide in the oxide sintered body, and whether or not the formed oxide semiconductor thin film is amorphous are confirmed through X-ray diffractometry (XRD).

In one example, the apparatuses and measurement conditions employed in the X-ray diffractometry are as follows.
X-ray diffractometer: RINT (product of Rigaku Corporation)
Scanning method: 2θ/θ method
Target: Cu
Tube voltage: 40 kV
Tube current: 20 mA
Scanning speed: 2,000°/min
Sampling width: 0.050°
Divergence slit: 1° Scattering slit: 1°
Receive slit: 0.3 mm

### (Composition)

The composition of the oxide sintered body is determined through scanning electron microscopy-energy dispersive X-ray spectroscopy (SEM-EDX).

An example of the apparatus and measurement conditions employed in the compositional analysis is as follows.
SEM-EDX: TM3030 (product of Hitachi High-Technologies)
Acceleration voltage: 15 kV
Detection element type: silicon drift detector
Area of element: 30 mm²
Energy resolution: 154 eV (Cu—Kα)
Detectable element: B₅ to Am₉₅
Qualitative analysis: auto/manual
Quantitative analysis: standard less method

### [Thin Film Transistor]

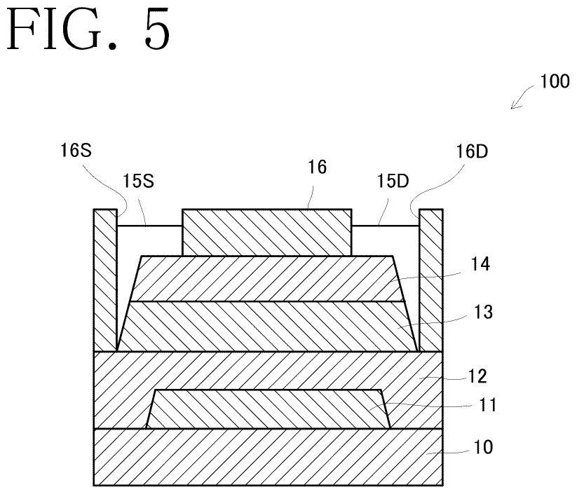

FIG. 5 shows a schematic configuration of an example of the thin film transistor of the present invention.

A thin film transistor 100 of the present embodiment has, on a substrate 10, a gate electrode 11, a gate insulating film 12, an active layer 13, a cap layer 14, a source electrode 15S, a drain electrode 15D, and a protective film 16.

The gate electrode 11 is formed of a conductive film disposed on a surface of the substrate 10. The substrate 10 is typically a transparent glass substrate. The gate electrode 11 is typically a metal single-layer film or a metal multi-layer film, the metal being molybdenum (Mo), titanium (Ti), aluminum (Al), copper (Cu), or the like, and is formed through, for example, sputtering. In the present embodiment, the gate electrode 11 is formed of molybdenum. No particular limitation is imposed on the thickness of the gate electrode 11, and the thickness is, for example, 200 nm. The gate electrode 11 is formed through a film formation technique such as sputtering or vacuum vapor deposition.

The active layer 13 serves as a channel layer of the thin film transistor 100. The thickness of the active layer 13 is, for example, 10 nm to 200 nm. The active layer 13 is formed of the oxide semiconductor thin film of the present invention. The active layer 13 is formed through a film formation technique such as sputtering.

The cap layer 14 may be a cap layer most suited for the oxide semiconductor thin film of the present invention having high electron mobility and wide band gap. A known cap layer which can suppress etching damage and a disadvantageous effect of hydrogen during CVD process may be employed.

The cap layer 14 and the active layer 13 are simultaneously patterned. Any of the aforementioned etchants may be used.

The gate insulating film 12 is provided between the gate electrode 11 and the active layer 13. The gate insulating film 12 is formed of, for example, silicon oxide film (Siox), silicon nitride film (SiNx), or a laminated film thereof. No particular limitation is imposed on the film formation method, and CVD, sputtering, vapor deposition, or the like may be employed. No particular limitation is imposed on the film thickness of the gate insulating film 12, and the thickness is, for example, 200 nm to 400 nm.

The source electrode 15S and drain electrode 15D are formed on the active layer 13 and the cap layer 14, respectively, such that the two electrodes are separate from each other. The source electrode 15S and the drain electrode 15D each may be formed of, for example, a metal single-layer film or a metal multi-layer film, the metal being aluminum, molybdenum, copper, titanium. As mentioned below, the source electrode 15S and the drain electrode 15D may be simultaneously formed by patterning a metal film. The thickness of the metal film is, for example, 100 nm to 200 nm. The source electrode 15S and the drain electrode 15D are formed through, for example, sputtering, vacuum vapor deposition, or a similar technique.

The source electrode 15S and the drain electrode 15D are coated with the protective film 16. The protective film 16 is formed of, for example, an electrically insulating material such as silicon oxide film (Siox), silicon nitride film (SiNx), or a laminated film thereof. The protective film 16 is provided so as to shield an element part including the active layer 13 and the cap layer 14 from outside air. No particular limitation is imposed on the film thickness of the protective film 16, and the thickness is, for example, 100 nm to 300 nm. The protective film 16 is formed through a film-formation method, for example, CVD.

After formation of the protective film 16, annealing is conducted, to thereby activate the active layer 13. No particular limitation is imposed on the annealing conditions. In the present embodiment, annealing is carried out in air at about 30 °C for 1 hour. In annealing, the cap layer 14 is conceived to suppress diffusion of hydrogen via heat transfer from the protective layer 16 to the active layer 13.

In the protective film 16, interlayer connection holes 16S, 16D are provided at appropriate positions for connecting the source electrode 15S and the drain electrode 15D to a wiring layer (not illustrated). The wiring layer is adapted to connect the thin film transistor 100 to a surrounding circuit (not illustrated) and formed of a transparent conductive film such as ITO.

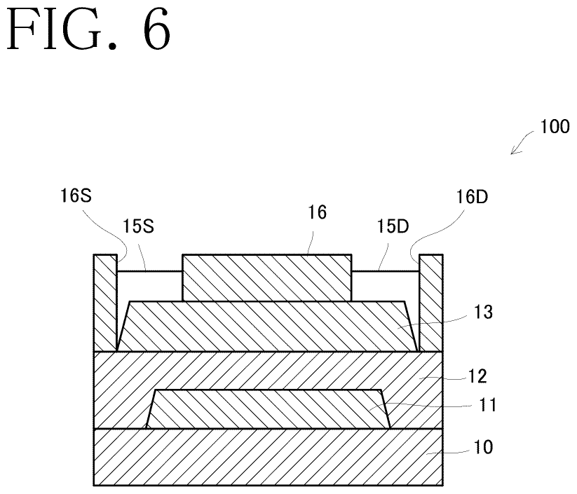

FIG. 6 shows a schematic configuration of another example of the thin film transistor of the present invention.

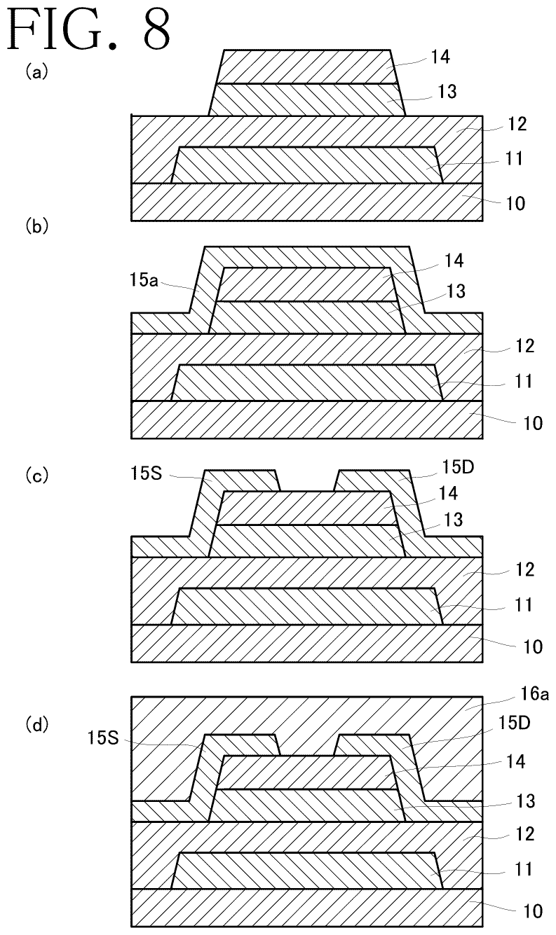

The example is the same as the thin film transistor of FIG. 8, except that no cap layer 14 of the thin film transistor shown in FIG. 5 is disposed. Thus, overlapping description will be omitted.

As described above, a thin film semiconductor transistor having an active layer formed of the oxide semiconductor thin film of the present invention may be used as a TFT for use in a high-function display device, even when the transistor has a structure shown in either FIG. 5 or 6. As a result, light resistance of the display is enhanced, leading to high reliability.

### (Method of Producing Thin Film Transistor)

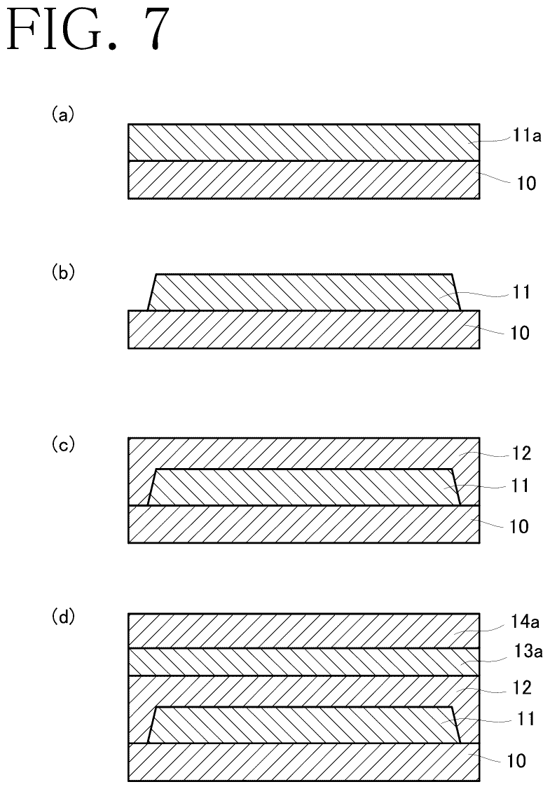

With reference to FIGS. 7 and 8, an embodiment of the method of producing the thin film transistor of the present invention will be described.

As shown in FIG. 7 (a), a gate electrode material layer 11a is formed on a substrate 10 through sputtering at room temperature. Then, as shown in FIG. 7 (b), a gate electrode 11 is formed by patterning through wet etching.

Subsequently, as shown in FIG. 7 (c), a gate insulating film 12 is formed through CVD. In the embodiment, an SiO_{X}/SiN_{X} stacked body is provided. Then, as shown in FIG. 7 (d), an active layer material layer 13a and a cap layer material layer 14a are sequentially formed through sputtering while the substrate 10 is maintained at 100 °C. Further, as shown in FIG. 8 (a), the active layer material layer 13a and the cap layer material layer 14a is patterned through etching, to thereby form an active layer 13 and a cap layer 14. Etching is conducted by use of an etchant, for example, a sulfuric acid-nitric acid-based etchant. Thereafter, in one annealing procedure, the stacked body is annealed in air at 400 °C for 1 hour. Subsequently, as shown in FIG. 8 (b), a source/drain metallic material layer 15a is formed through sputtering at room temperature, and as shown in FIG. 8 (c), a source electrode 15S and a drain electrode 15D are formed through patterning. Finally, as shown in FIG. 8 (d), a protective film material layer 16a is formed through CVD. The protective film material layer 16a is, for example, an SiOx film having a thickness of 300 nm. The protective film material layer 16a is annealed in air at 300 °C and then patterned through dry etching, to thereby form interlayer connection holes 16S, 16D with respect to the source electrode 15S and the drain electrode 15D.

The thin film transistor (TFT) according to the present invention as described above has the cap layer 14 formed of the aforementioned oxide thin film containing indium, magnesium, and tin. In this case, no shifting of Vth of the TFT occurs during stacking of the cap layer 14 on the high-electron mobility active layer 13 formed of a material which tends to exhibit a small band gap Eg. Thus, external undesired factors in fabrication of TFTs can be successfully suppressed.

More specifically, the cap layer 14 of the present invention can suppress damage to the active layer 13 during a hydrogen process in fabrication of TFTs and patterning of the source electrode 15S and the drain electrode 15D.

The thin film semiconductor transistor as shown in FIG. 6 having no cap layer 14 may be fabricated through the same manner, except that the cap layer 14 is not formed.

In any case, a thin film semiconductor transistor having an active layer formed of the oxide semiconductor thin film of the present invention may be used as a TFT for use in a high-function display device, even when the transistor has a structure shown in either FIG. 5 or 6. As a result, light resistance of the display is enhanced, leading to high reliability.

### EXAMPLES

### Sputtering Targets: Examples 1 to 6 and Comparative Examples 1 to 4

Indium oxide, gallium oxide, germanium oxide, and zinc oxide, and optional tin oxide were weighed so that the compositions shown in Table 2 below were attained, and mixed by means of a ball mill. The thus-obtained particle powder was fired in air, to thereby yield a sintered body.

Table 2 shows measurements of relative density and specific resistivity of the yielded sintered bodies. In addition, variation in the composition of the thus-mixed particle powder and the oxide sintered body (i.e., before and after sintering) was checked through EDX. Table 2 also shows the results. Notably, formation of a complex oxide having a specific composition was successfully confirmed through XRD.

In the Examples, indium oxide, gallium oxide, germanium oxide, and zinc oxide, and optional tin oxide were used as raw materials, and the mixture was fired in air, to thereby yield sintered bodies each having a relative density of 90% or higher. Particularly when sintering was completed at 1,300 °C or higher, the formed sintered body was found to have a relative density of 97% or higher and a specific resistivity of 10 mΩ·cm or less.

Notably, in the Comparative Examples, when the sintering temperature was lower than 1,100 °C, sufficient sintering did not occur, thereby providing a relative density lower than 90%. Also, when firing was conducted at 1,650 °C or higher, sublimation of zinc oxide occurred, and a weight loss of about 7% was measured before and after sintering, resulting in variation in composition.

TABLE 2

| | | | | | | | | | | | Firing | | | Relative | Specific | |
|---|---|---|---|---|---|---|---|---|---|---|---|---|---|---|---|---|
| | Composition (%) | | | | | Raw materials | | | | | temp. | Time | | density | resistivity | Variation |
| | In | Ga | Ge | Sn | Zn | In | Ga | Ge | Sn | Zn | (°C) | (hr) | Atmosphere | (%) | (mΩcm) | in composition |
| Ex. 1 | 45 | 22 | 2 | 0 | 31 | In₂O₃ | Ga₂O₃ | GeO₂ | SnO₂ | ZnO | 1360 | 5 | air | 99.7 | 4 | no |
| Ex. 2 | 50 | 15 | 2 | 3 | 30 | In₂O₃ | Ga₂O₃ | GeO₂ | SnO₂ | ZnO | 1360 | 5 | air | 99.9 | 3 | no |
| Ex. 3 | 45 | 22 | 2 | 0 | 31 | In₂O₃ | Ga₂O₃ | GeO₂ | SnO₂ | ZnO | 1150 | 5 | air | 90.5 | 15 | no |
| Ex. 4 | 45 | 22 | 2 | 0 | 31 | In₂O₃ | Ga₂O₃ | GeO₂ | SnO₂ | ZnO | 1600 | 5 | air | 99.9 | 3 | no |
| Ex. 5 | 50 | 15 | 2 | 3 | 30 | In₂O₃ | Ga₂O₃ | GeO₂ | SnO₂ | ZnO | 1150 | 5 | air | 90.9 | 14 | no |
| Ex. 6 | 50 | 15 | 2 | 3 | 30 | In₂O₃ | Ga₂O₃ | GeO₂ | SnO₂ | ZnO | 1600 | 5 | air | 99.9 | 2 | no |
| Comp. 1 | 45 | 22 | 2 | 0 | 31 | In₂O₃ | Ga₂O₃ | GeO₂ | SnO₂ | ZnO | 1050 | 5 | air | 86.7 | 20 | no |
| Comp. 2 | 50 | 15 | 2 | 3 | 30 | In₂O₃ | Ga₂O₃ | GeO₂ | SnO₂ | ZnO | 1700 | 5 | air | 99.3 | 3 | yes |
| Comp. 3 | 45 | 22 | 2 | 0 | 31 | In₂O₃ | Ga₂O₃ | GeO₂ | SnO₂ | ZnO | 1050 | 5 | air | 88.5 | 18 | no |
| Comp. 4 | 50 | 15 | 2 | 3 | 30 | In₂O₃ | Ga₂O₃ | GeO₂ | SnO₂ | ZnO | 1700 | 5 | air | 99.5 | 2 | yes |

### Oxide Semiconductor Thin Films: Examples 11 and 12

By use of the sputtering targets of Examples 1 and 2, oxide semiconductor thin films were formed. As mentioned above, electron mobility, band gap, etching rate to a specific etchant were measured. Table 3 shows the results.

### Oxide Semiconductor Thin Films: Comparative Examples 11 to 13

By use of various sputtering targets, oxide semiconductor thin films having compositions shown in Table 3 were formed. As mentioned above, electron mobility, band gap, etching rate to a specific etchant were measured. Table 3 shows the results. Also, whether or not each of the formed films was amorphous was investigated through XRD. Table 3 shows the results.

In the results, the oxide semiconductor thin films of Examples 11 and 12 were found to have satisfactory characteristics in terms of electron mobility, band gap, and etching rate. However, the thin films of Comparative Examples 11 to 13 failed to achieve satisfactory characteristics in all aspects.

TABLE 3

| | | | | | | | Carrier | | Etching rate | |
|---|---|---|---|---|---|---|---|---|---|---|
| Ex. | Composition (%) | | | | | Mobility | concentration | Band gap | (nm/sec) | |
| Comp. Ex | In | Ga | Ge | Sn | Zn | (cm²/V · s) | (/cm³) | (eV) | PAN | XRD |
| Ex. 11 | 45 | 22 | 2 | 0 | 31 | 18.1 | 4.3E+16 | 2.8 | 3.0 | amorphous |
| Ex. 12 | 50 | 15 | 2 | 3 | 30 | 18.5 | 6.8E+16 | 2.8 | 3.4 | amorphous |
| Comp. 11 | 10 | 22 | 6 | 10 | 52 | 5.0 | 1.0E+13 | 3.1 | 3.1 | amorphous |
| Comp. 12 | 40 | 5 | 5 | 30 | 20 | 19.8 | 1.0E+17 | 3.2 | 2.9 | amorphous |
| Comp. 13 | 70 | 0 | 0 | 5 | 25 | 29.3 | 1.0E+19 | 2.6 | 2.6 | amorphous |

### Thin Film Transistors: Examples 21 and 22

Thin film transistors of Examples 21 and 22 having a structure as shown in FIG. 6 (i.e., having no cap layer 14) were fabricated.

The active layer 13 was formed by use of In—Sn—Ga—Ge—O of Example 11 or 12 (as exemplified in Table 3) so as to have a film thickness of 50 nm.

The thin film transistors of the Examples each had an active layer having oxide elemental proportions represented by In_{X}Sn_{Y}Ga_{V}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied. Thus, TFT characteristics of the transistors were measured.

### Thin Film Transistor: Comparative Example 21

A thin film transistor of Comparative Example 21 was fabricated in a manner similar to that of Example 21, except that the active layer 13 was formed by use of commercial ITGZO so as to have a film thickness of 50 nm.

Comparative Example 21 corresponded to a thin film transistor having an active layer formed from existing ITGZO material, and TFT characteristics thereof were measured.

### Thin Film Transistors: Examples 23 and 24

Thin film transistors of Examples 23 and 24 having a structure as shown in FIG. 5 (i.e., having a cap layer 14) were fabricated.

The active layer 13 was formed by use of In—Sn—Ga—Ge—O of Example 11 or 12 (as exemplified in Table 3) so as to have a film thickness of 50 nm.

The cap layer was formed by use of commercial IGZO 136 so as to have a film thickness of 15 nm.

The thin film transistors of the Examples each had an active layer having oxide elemental proportions represented by In_{X}Sn_{Y}Ga_{V}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied, and a cap layer serving as an upper layer. Thus, TFT characteristics of the transistors were measured.

### Thin Film Transistor: Comparative Example 22

A thin film transistor of Comparative Example 22 was fabricated in a manner similar to that of Example 23, except that the active layer 13 was formed by use of commercial IGZO so as to have a film thickness of 50 nm.

Comparative Example 22 corresponded to a thin film transistor having an active layer formed from existing ITGZO material, and a cap layer serving as an upper layer. Thus, TFT characteristics thereof were measured.

### (Comparison of TFT Characteristics)

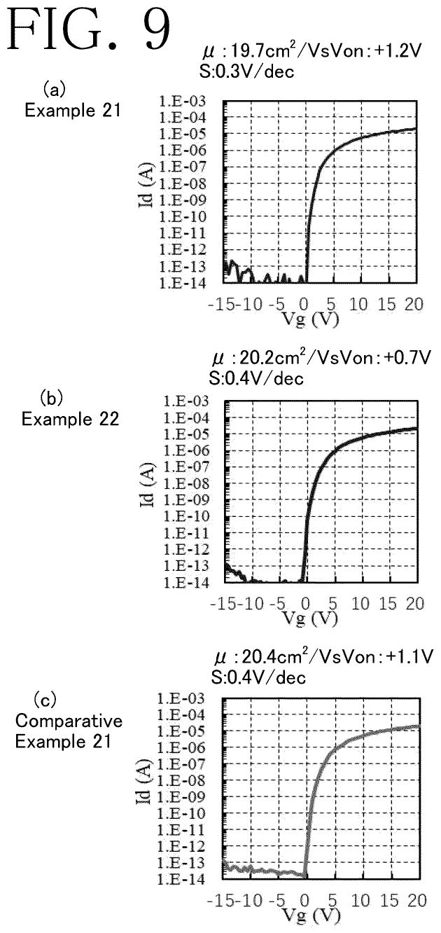

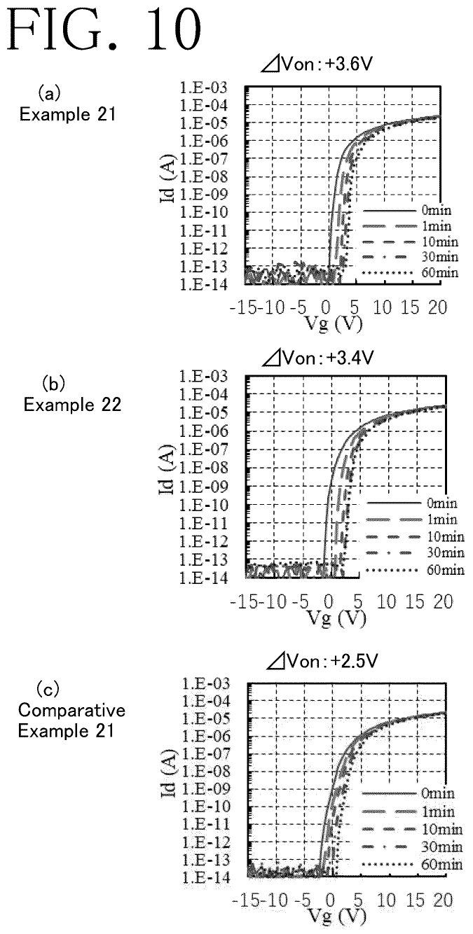

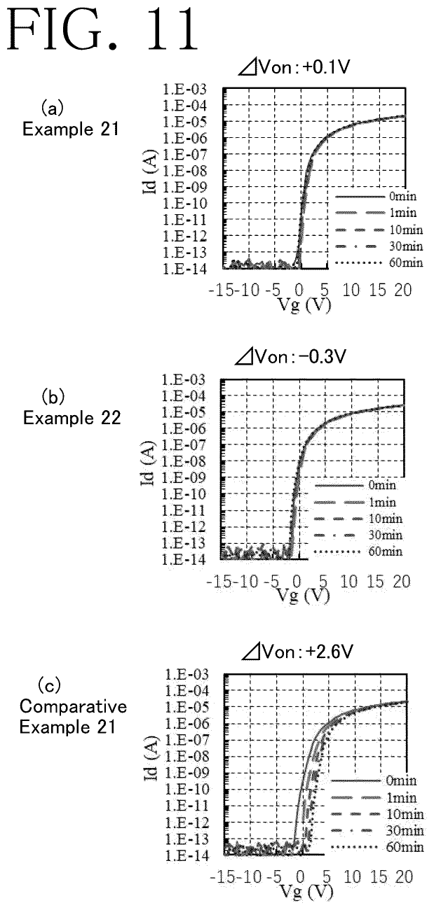

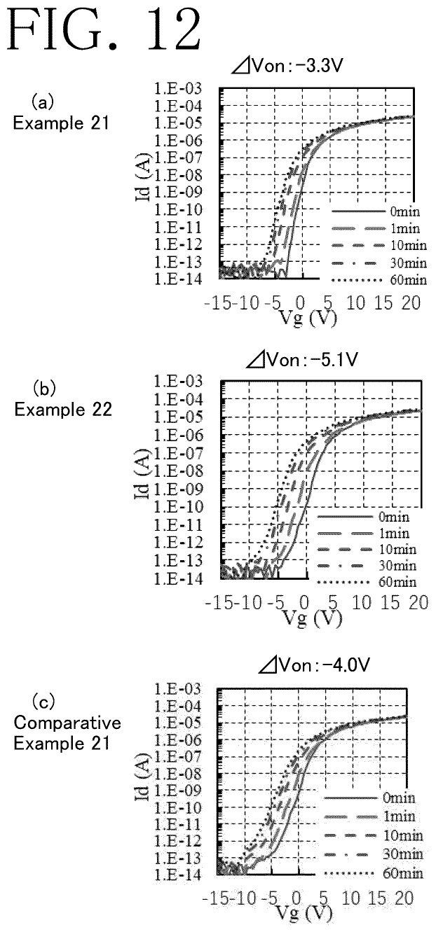

Thin film transistors of Examples 21 and 22 and Comparative Example 21 were assessed in terms of initial characteristics, PBTS (positive bias temperature stress), NBTS (negative bias temperature stress), and NBITS (negative bias illustration temperature stress). FIGS. 9 to 12 show the results the above measurements. In FIGS. 9 to 12, (a), (b), and (c) correspond to Example 21, Example 22, and Comparative Example 21, respectively.

As shown in the graphs, the thin film transistors of the Examples were found to provide electron mobility almost equal to or higher than those of the thin film transistor of the Comparative Example, and light resistance (NBITS) equal to or higher than those of the thin film transistor of the Comparative Example.

Thus, stress test characteristics were found to be enhanced on the basis of the material concept of the present invention.

### (Comparison of TFT Characteristics)

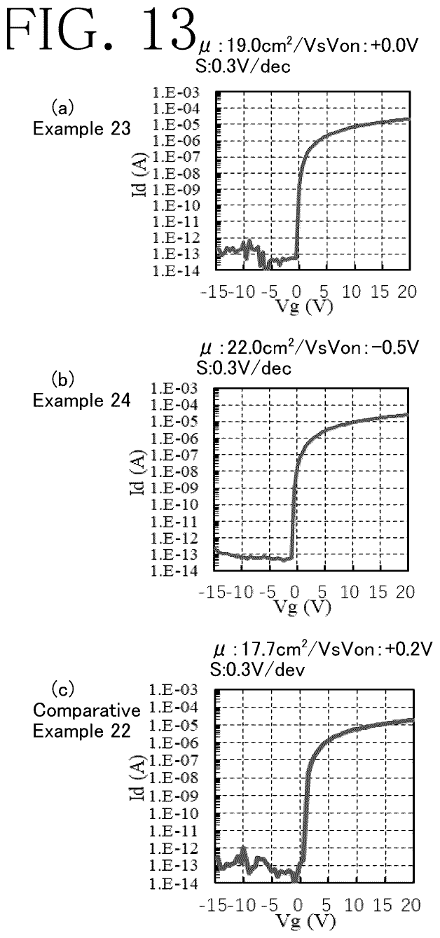

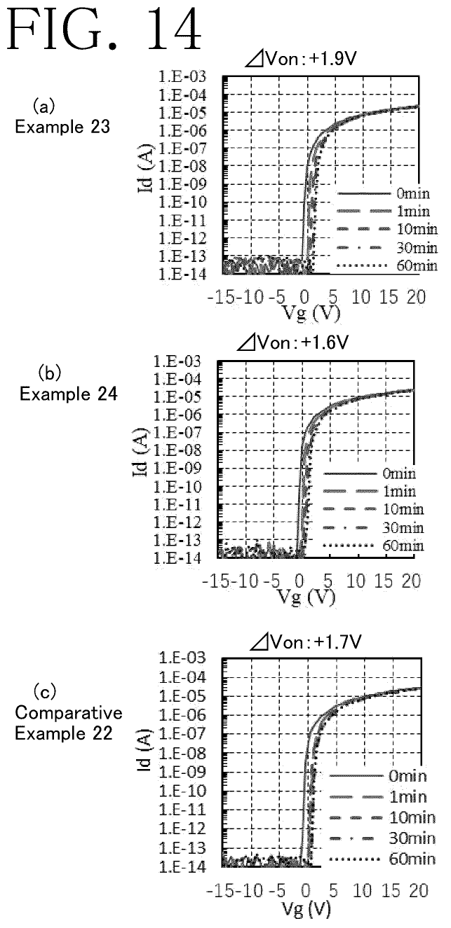

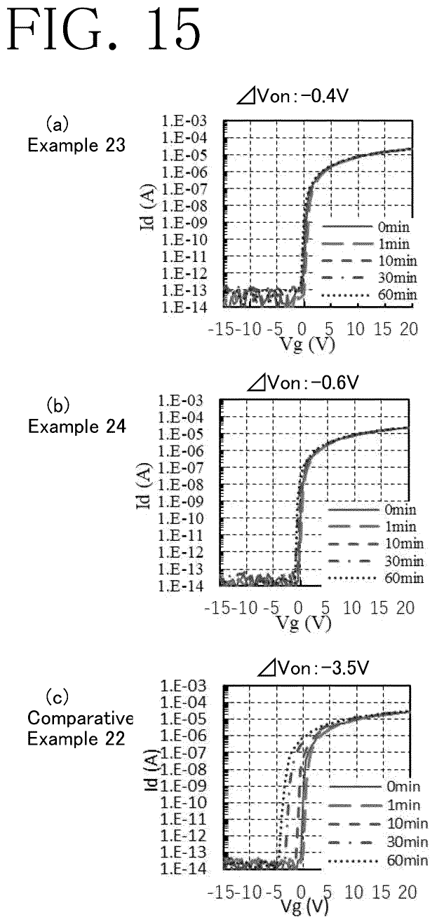

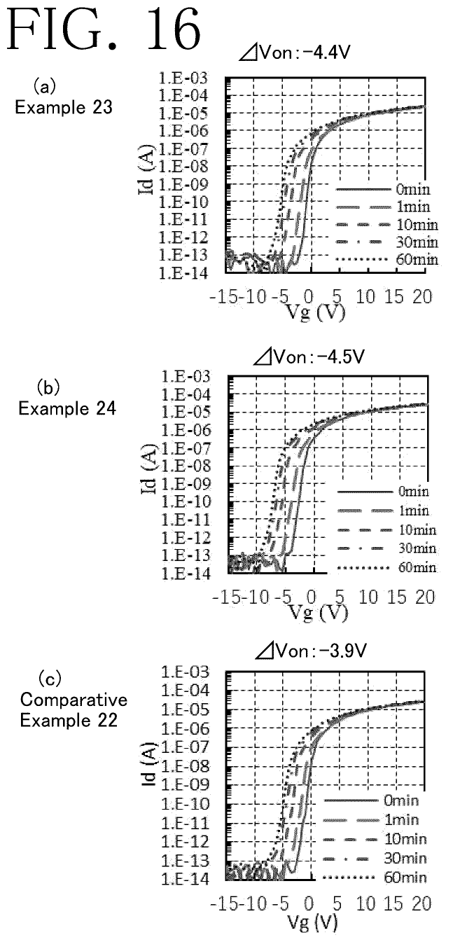

Thin film transistors of Examples 23 and 24 and Comparative Example 22 were assessed in terms of initial characteristics, PBTS (positive bias temperature stress), NBTS (negative bias temperature stress), and NBITS (negative bias illustration temperature stress). FIGS. 13 to 16 show the results the above measurements. In FIGS. 13 to 16, (a), (b), and (c) correspond to Example 23, Example 24, and Comparative Example 22, respectively.

As shown in the graphs, the thin film transistors of the Examples were found to provide electron mobility almost equal to or higher than those of the thin film transistor of the Comparative Example, and suitable reliability (PBTS, NBTS).

### DESCRIPTION OF REFERENCE NUMERALS

10: substrate
11: gate electrode
11a: gate electrode material layer
12: gate insulating film
13: active layer
13a: active layer material layer
14: cap layer
14a: cap layer material layer
15a: source drain metallic material layer
15S: source electrode
15D: drain electrode
16: protective film
16a: protective film material layer
16S, 16D: interlayer connection hole
100: thin film transistor

1. A sputtering target for forming an oxide semiconductor thin film which target can form the oxide semiconductor thin film,
wherein the target is formed of an oxide sintered body containing a specific oxide,
the specific oxide has elemental proportions, wherein a composition of a specified oxide is represented by In_{X}Sn_{Y}Ga_{V}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied,
the composition of the specific oxide does not deviate from a composition calculated from a blending of raw materials, and
the target has a relative density of 90% or more, and a specific resistivity of 10 mΩcm or less.

2. The sputtering target for forming the oxide semiconductor thin film according to claim 1, wherein the oxide sintered body further contains a group A element, which is defined as at least one element selected from among Ti, Ta, Zr, Y, Al, Mg, and Sb.

3. The sputtering target for forming the oxide semiconductor thin film according to claim 2, wherein the target contains Ti in an amount of 2% or less, Ta in an amount of 2% or less, Zr in an amount of 3% or less, Y in an amount of 4% or less, Al in an amount of 5% or less, Mg in an amount of 5% or less, and Sb in an amount of 9% or less, and the group A element content is less than 10%.

4. (canceled)

5. A method for producing the sputtering target for forming the oxide semiconductor thin film which the target can form the oxide semiconductor thin film, the method comprising:
mixing indium oxide powder, tin oxide powder, zinc oxide powder, gallium oxide powder, and germanium oxide powder, to thereby form a compact, and firing the compact at 1,100 °C to 1,650 °C, to thereby yield the sputtering target for forming the oxide semiconductor thin film, the target having the oxide sintered body according to claim 1.

6. A method for producing the sputtering target for forming the oxide semiconductor thin film which the target can form the oxide semiconductor thin film, the method comprising:
mixing an oxide, a hydroxide, or a carbonate salt of indium, tin, zinc, gallium, and germanium; calcining the mixture at 600 °C to 1,500 °C, to thereby form a precursor powder; molding the precursor powder, to thereby form a compact; and firing the compact at 1,100 °C to 1,650 °C, to thereby yield the sputtering target for forming the oxide semiconductor thin film, the target having the oxide sintered body according to claim 1.

7. An oxide semiconductor thin film, wherein the thin film is formed of an oxide semiconductor containing a specific oxide, and the specific oxide has elemental proportions represented by In_{X}Sn_{Y}Ga_{V}Ge_{w}Zn_{Z}, wherein X is 0.4 to 0.8, Y is 0 to 0.1, and Z is 0.2 to 0.6, and conditions X+Y+Z=1, V/(V+W+X+Y+Z) of 0.01 to 0.22, and W/(V+W+X+Y+Z) of 0.01 to 0.06 are satisfied.

8. The oxide semiconductor thin film according to claim 7, which exhibits an electron mobility of 15 to 30 cm²/V·s and a band gap of 2.75 eV or more.

9. The oxide semiconductor thin film according to claim 7, wherein an etching rate in etching with a phosphoric acid-acetic acid-based etchant is 1 nm/sec or more.

10. The oxide semiconductor thin film according to claim 7, wherein the thin film further contains a group A element, which is defined as at least one element selected from among Ti, Ta, Zr, Y, Al, Mg, and Sb.

11. The oxide semiconductor thin film according to claim 10, wherein the thin film contains Ti in an amount of 2 at % or less, Ta in an amount of 2 at % or less, Zr in an amount of 3 at % or less, Y in an amount of 4 at % or less, Al in an amount of 5 at % or less, Mg in an amount of 5 at % or less, and Sb in an amount of 9 at % or less, and the group A element content is less than 10 at %.

12. A thin film semiconductor device, which comprises:
a gate electrode;
a gate insulating film disposed on the gate electrode;
an active layer formed of the oxide semiconductor thin film exhibiting a high electron mobility and disposed on the gate insulating film; and
a source electrode and a drain electrode which are connected to the active layer,
wherein the active layer is formed of the oxide semiconductor thin film according to claim 7.

13. The thin film semiconductor device according to claim 12, wherein the device includes a cap layer which is disposed so as to cover the active layer.

14. The thin film semiconductor device according to claim 13, wherein the cap layer has an etching rate suited for patterning with the active layer.

15. A method for producing the thin film semiconductor device as recited in according to claim 12, the method comprising:
forming the gate insulating film on the gate electrode;
forming the active layer formed of the oxide semiconductor thin film exhibiting the high electron mobility on the gate insulating film through sputtering;
patterning the active layer;
forming a metal layer disposed on the active layer which has been patterned and serves as an underlayer film; and
patterning the metal layer through wet etching, to thereby form the source electrode and the drain electrode.

16. A method for producing the thin film semiconductor device according to claim 13, the method comprising:
forming the gate insulating film on the gate electrode;
forming the active layer formed of the oxide semiconductor thin film exhibiting the high electron mobility on the gate insulating film through sputtering;
forming the cap layer on the active layer through sputtering;
patterning a stacked film of the active layer and the cap layer;
forming a metal layer disposed on the active layer and the cap layer which have been patterned and serve as an underlayer film; and
patterning the metal layer through wet etching, to thereby form the source electrode and the drain electrode.
